(19) United States
(12) Patent Application Publication
(10) Pub. No.: US 2006/0243992 A1
(43) Pub. Date: Nov. 2, 2006

(54) Semiconductor light-emitting device

(75) Inventors: Nobuyuki Ikoma, Yokohama-shi (JP); Takahiko Kawahara, Yokohama-shi (JP); Masato Furukawa, Yokohama-shi (JP)

Correspondence Address: SMITH, GAMBRELL & RUSSELL, 1850 M STREET, N.W., SUITE 800, WASHINGTON, DC, 20036, US

(73) Assignee: Sumitomo Electric Industries, Ltd.

(21) Appl. No.: 11/453,837

(22) Filed: Jun. 16, 2006

Related U.S. Application Data
(63) Continuation-in-part of application No. 11/020,662, filed on Dec. 27, 2004.

(30) Foreign Application Priority Data
Jun. 24, 2005 (JP) 2005-185334
Dec. 26, 2003 (JP) 2003-433972

(51) Int. Cl. H01L 33/00

(52) U.S. Cl. 257/94

(57) ABSTRACT

The present invention provides a light-emitting device with a quantum well structure comprising a barrier layer containing aluminum, gallium, indium and arsenic, which reduces the leak current flowing in the buried layer. The buried layer includes first and second buried layers stacked to each other and covers the sides of the quantum well structure. The barrier layer induces a tensile stress to lower the band gap energy, to increase the band gap wavelength λ_{BG} greater than or equal to 1.0 μm.

### RELATED APPLICATIONS

This application is a continuation-in-part application of application Ser. No. 11/020,662, filed Dec. 27, 2004, entitled “Semiconductor light-emitting device,” and assigned to the Assignee of the present application. This application is closely related to a pending application, Ser. No. of which is 11/280,823, filed Nov. 17, 2005, entitled “Distributed feedback laser including AlGaInAs in feedback grating layer.”

### BACKGROUND OF THE INVENTION

1. Field of the Invention

The present invention relates to a semiconductor light-emitting device, in particular, relates to a semiconductor laser diode.

2. Related Prior Art

As increasing a mass of the optical communication, light-emitting devices able to be modulated with higher frequencies and to be produced with lower cost are required. Semiconductor laser diodes with emitting wavelengths within 1.3 μm band by directly modulating without any control means of temperatures there of such as a Peltier device are attracted to satisfy the requirement above. Such laser diodes are necessary to show a superior performance at high temperatures because the apparatus installing those laser diodes does not provide any temperature control means. Semiconductor materials based on AlGaInAs, instead of InGaAsP based materials widely used in an active layer of the semiconductor laser diode for the optical communication, brings advantages to enhance the temperature characteristic of the laser diode. After growing semiconductor layers including the active layer on the InP substrate, an etching forms a mesa strive to be buried by current blocking layers in both sides thereof. Such buried semiconductor laser shows performances of a low threshold current and a stable transverse mode because the current is effectively confined in the mesa stripe by the current blocking layers. The current blocking layers may be generally a combination of a p-type InP and an n-type InP.

The Japanese Patent published as JP-2000-286508A has disclosed one type of the semiconductor laser that provides an optical waveguide having a lower cladding layer, a core layer, a first upper cladding layer, and a second upper cladding layer. These layers are stacked so as to form a channel including the first upper cladding layer and the core layer. The channel includes, on the lower cladding layer, a lower SCH (Separated Confinement Hetero-structure) layer made of InGaAsP, a hole stopping layer, an active layer made of Salinas with an emitting wavelength in 1.3 μm band, an electron stopping layer, and an upper SCH layer made of InGaAsP. The core layer stacks these layers in this order. The relatively small concentration of aluminum (Al) in the channel prevents the growth of the native oxide film of aluminum therein. Thus, this patent provides a semiconductor laser diode operable in high temperatures by an enhanced carrier injection efficiency and a method for manufacturing it.

A paper (IEEE J. of Quantum Electronics, vol. 25(6) (1989) pp. 1369) has analyzed a leak current of the laser diode comprised of the InGaAsP/InP based system with the buried hetero-structure and the emitting wavelength in the 1.3 μm band. This laser diode has the current blocking layer of the reversely biased p-n junction. The analysis has used a model of the laser diode that a parasitic thyristor with a p-n-p-n junction is formed in a side of an active region with a p-n junction, and has indicated that, to reduce the leak current, the active layer may be arranged so as to be in contact with the p-layer in the current blocking layer.

Inventors of the present invention has developed a light-emitting device with an active layer buried by a stack of an n-type InP layer and a p-type InP layer. The active layer includes a layer made of AlGaInAs with a band gap wavelength in the 1.3 μm band. However, the light-emitting device did not emit light with the expected output power, and the inventors has found that the reason why the expected power is not obtained is due to the leak current flowing in the current blocking layer. While, the laser diode based on the InGaAsP/InP system has realized the far small leak current.

The present invention, which was invented by taking the above backgrounds into account, is to provide a light-emitting device with an active region with a quantum well structure including a barrier layer made of at least aluminum (Al), gallium (Ga), indium (In), and arsenic (As) that may reduce the leak current.

### SUMMARY OF THE INVENTION

According to one aspect of the present invention, a semiconductor light-emitting device is provided, which comprises a semiconductor substrate, an active region, and a buried semiconductor region. The substrate is made of a III-V compound semiconductor material with a first conduction type. The active region, which is arranged on the substrate, provides a quantum well structure including a barrier layer and a quantum well layer. The barrier layer is made of a first III-V compound semiconductor material with a band gap wavelength greater than or equal to 1 μm and contains aluminum (Al), gallium (Ga), indium (In) and arsenic (As). The quantum well layer is made of a second III-V compound semiconductor material. The buried semiconductor region, which is arranged on the substrate and provided on sides of the active region, includes first and second buried semiconductor layers. The first buried layer has a second conduction type different from the first conduction type, while, the second buried layer has the first conduction type. The second buried layer is arranged on the first buried layer. The first buried layer with the second conduction type is in contact with the active region, in particular, is in contact with the barrier layer in the quantum well structure. In the present invention, the barrier layer is induced by a tensile stress.

Since the barrier layer in the quantum well structure, which contains Al, Ga, In, and As, is induced by the tensile stress that raises the light hole band of the valence band to narrower the band gap energy thereof, the carrier injection from the barrier layer to the buried layer with the second conduction type may be suppressed to decrease the leak current flowing in the buried region by causing the parasitic thyristor structure to be turned on.

The band gap wavelength of the barrier layer is preferably greater than or equal to 1 μm, and is smaller than or equal to 1.15 μm to make the suppressed leak current in consistent with the differential gain of the light-emitting device.

The quantum well layer may also include aluminum, gallium, indium, and arsenic, but has a composition different from that of the barrier layer. More preferably, the quantum well layer may induce the compressive stress to raise the heavy hole band in the valence band, which may enhance the quantum effect in the well layer and compensate the tensile stress induced in the barrier layer.

The buried region, in particular, the first and second buried semiconductor layers are made of an n-type InP and a p-type InP, respectively. Even the combination of the InP in the buried layer and the AlGaInAs in the barrier layer, the leak current in the buried region may be suppressed because the band discontinuity of the conduction band between the AlGaInAs barrier layer and the p-type InP layer in the buried layer may become small by the band gap wavelength of the barrier layer greater than or equal to 1 μm and by the tensile stress induced therein.

### BRIEF DESCRIPTION OF DRAWINGS

FIG. 1A is a perspective view showing a light-emitting device according to the first embodiment of the present invention, and FIG. 1B is a schematic diagram of the active region of the light-emitting device shown in FIG. 1A;

FIG. 2A is a schematic model used in the calculation of the band diagram, and FIGS. 2B and 2C are the results of the band discontinuity to the InP each calculated by using the band discontinuity ratio, ΔEc:ΔEv=0.4:0.6, for the InGaAsP/InP system lattice matched to the InP and the ratio, ΔEc:ΔEv=0.72:0.28, for the AlGaInAs/InP system lattice matched to the InP;

FIG. 3 is a calculative result of the leak current against the band gap wavelength of the AlGaInAs barrier layer;

FIG. 4 is a calculative result of the differential gain against the band gap wavelength of the AlGaInAs barrier layer;

FIG. 5 schematically shows band diagrams of the AlGaInAs barrier layer lattice matched to the InP and the AlGaInAs barrier layer with a tensile stress due to be 0.5% lattice-mismatching to the InP;

FIG. 6 shows the band discontinuity of the conduction band between the InP and the AlGaInAs against the band gap wavelength of the AlGaInAs;

FIG. 7A shows a modification of the second embodiment, and FIG. 7B shows another modification of the second embodiment;

from FIGS. 8A to 8C show processes according to third embodiment of the present invention for manufacturing the light-emitting device;

from FIGS. 9A to 9C show processes of the third embodiment subsequent to the process shown in FIG. 8C;

FIG. 10 is a table showing an exemplary configuration of semiconductor layers applied to the first embodiment; and

FIG. 11 is a table showing an arrangement of the active region according to the second embodiment of the present invention.

### DESCRIPTION OF PREFEREED EMBLDIMENTS

### First Embodiment

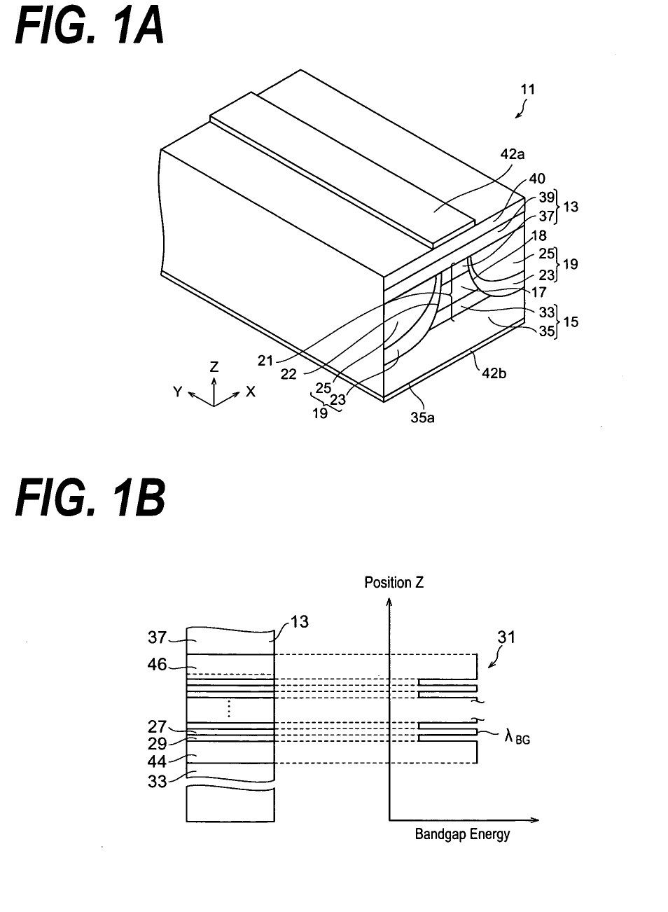

FIG. 1A shows a light-emitting device according to the first embodiment of the invention, and FIG. 1B schematically shows a structure in the active region of the light-emitting device shown in FIG. 1A. The light-emitting device 11 has a semiconductor region 13 with a second conduction type, a semiconductor region 15 with a first conduction type, an active region 17, and a buried semiconductor region 19. The active region 17 is put between the region 13 with the second conduction type and the region 33 with the first conduction type, and is within the mesa 21. The buried region 19, also put between the region 13 with the second conduction type and the region 15 with the first conduction type, and covers the side 22 of the mesa 21 and the top of the region 15 with the first conduction type. The buried region 19 includes a buried layer 23 with the second conduction type and another buried layer 25 with the firs conduction type. The former layer 23, the buried layer with the second conduction type covers sides 18 of the active region 17 and the top of the region 15 with the first conduction type. The latter layer 25, the buried layer with the first conduction type, covers the buried layer 23 with the second conduction type. The active region 17 includes a quantum well structure 31 comprising of a plurality of well layers 29 and a plurality of barrier layers 27, and the barrier layers 27 are made of a first III-V semiconductor material containing aluminum (Al), gallium (Ga), indium (In) and arsenic (As) with a band gap frequency λ_{BG} greater than or equal to 1.0 μm.

The region 15 with the first conduction type includes a layer 33 made of a group III-V semiconductor material with the first conduction type and is included within the mesa 21. The layer 33 is formed on a conductive semiconductor substrate 35. The region 13 with the second conduction type includes a first layer 37 made of a III-V semiconductor material with the second conduction type and is included within the mesa 21. On the layer 37 with the second conduction type and the buried region 19 are formed with a second layer 39 made of a III-V semiconductor material with the second conduction type. The layer 33 with the first conduction type operates as a cladding layer with the first conduction type, while the first and second layers, 37 and 39, operate as another cladding layer with the second conduction type.

The light-emitting device 11 further provides a contact layer 40 on the second layer 39. On the contact layer 40 is provided with a first electrode 42a that positions on the mesa 21, whereas the back surface 35a of the substrate 35 forms a second electrode 42b.

In the light-emitting device 11, the active region 17 includes an optical guiding layer 44 put between the well layer 29 and the layer 33 with the first conduction type. The active region 17 further includes another optical guiding layer 46 put between the well layer and the first layer 37 with the second conduction type.

The light-emitting device 11 in the well layer 29 thereof may be made of a second III-V semiconductor material containing aluminum, gallium, indium, and arsenic with a band gap wavelength longer than that of the first semiconductor material of the barrier layer, for instance, the band gap wavelength of the well layer may be 1.4 μm. While, the band gap wavelength of the first semiconductor material of the barrier layer 27 may be greater than 1.05 μm. According to such relation of the band gap wavelength between the barrier layer 27 and the well layer 29 and that of the barrier layer being greater than or equal to 1.05 μm, the leak current flowing in the buried region may be reduced.

Moreover, the band gap wavelength of the first material of the barrier layer 27 may be shorter than or equal to 1.15 μm to enhance a differential gain of the light-emitting device and a high frequency performance thereof.

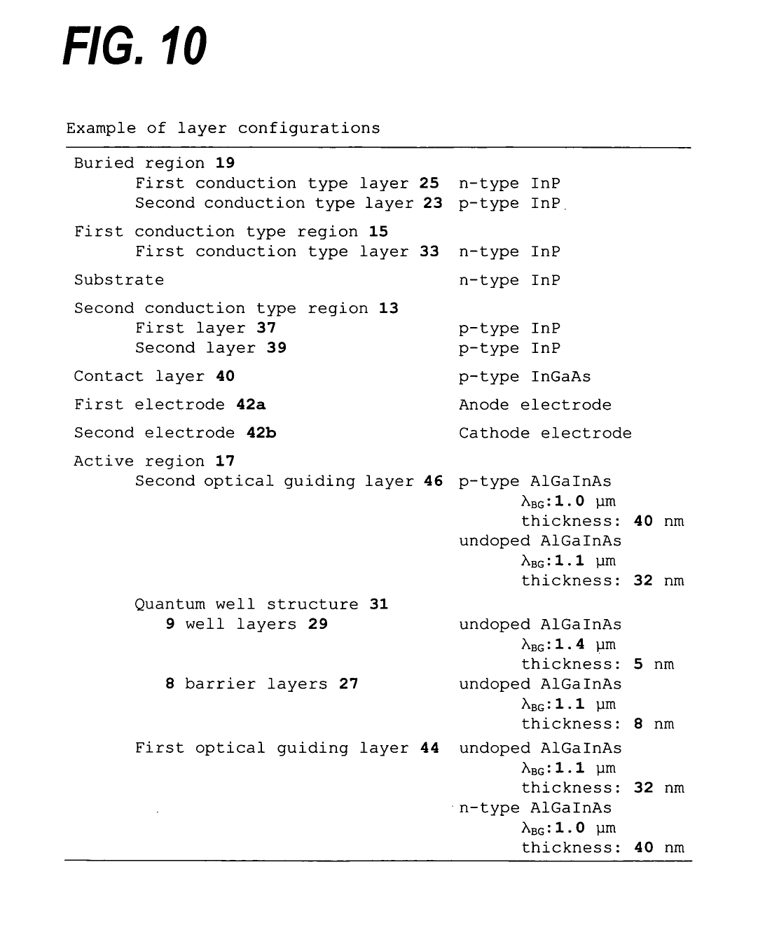

One preferred example of layer configurations described above is shown in FIG. 10. The embodiment shown above in the quantum well structure 31 thereof does not show any stress in the well and barrier layers, 29 and 27, due to the lattice matching, and is suitable for the semiconductor laser diode emitting in the 1.3 μm wavelength band.

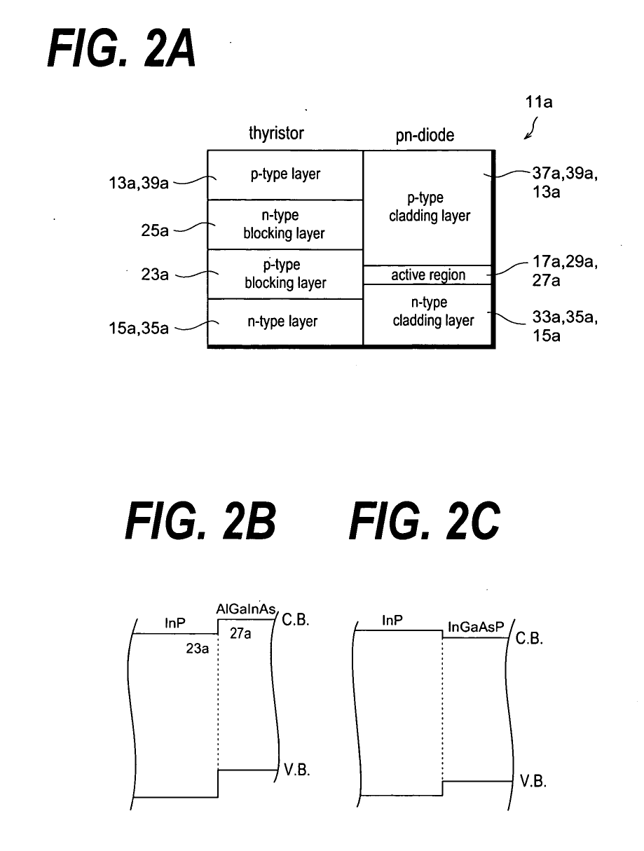

The reason why the embodiment mentioned above may reduce the leak current will be described below as referring to FIGS. 2A to 2C. A light-emitting device with an active layer buried by an n-type InP and a p-type InP may be modeled in FIG. 2A. In this model, a parasitic thyristor with the p-n-p-n configuration comes in contact with the pn junction diode in the active layer. More specifically, the active layer comes in contact with the p-type current blocking layer.

FIG. 2B is a calculative result of the band discontinuity in the conduction and valence bands between the AlGaInAs barrier layer 27a and the p-type current blocking layer 23a, which is carried out based on a parameter, ΔEc:ΔEv=0.72:0.28, of the band discontinuity ratio that is widely used in the AlGaInAs/InP system lattice-matched with the InP substrate. While, FIG. 2C is a calculative result of the band discontinuity in the conduction and valence bands, when the p-type InP is assumed for the current blocking layer against the InGaAsP barrier layer 27a, which is carried out by a parameter, ΔEc:ΔEv=0.4:0.6, of the band discontinuity ratio widely used for the InGaAsP/InP system lattice-matched with the InP substrate. These figures are compared to strengthen the function of the present invention. For the InGaAsP/InP system in FIG. 2C, the bottom level of the conduction band in the InGaAsP is lowered by about 7.0×10⁻²⁰ Joule (44 meV) against the bottom level of the conduction band in the InP. While, for the AlGaInAs/InP system in FIG. 2B, the bottom of the conduction band of the AlGaInAs is higher than that of the InP by about 1.68×10⁻²⁰ Joule (105 meV).

As shown in FIG. 2A, the active layer comes in contact with the p-type current blocking layer. In the case that the barrier layer is made of InGaAsP, as shown in FIG. 2C, the bottom level of the conduction band of the InGaAsP is lowered to that of the InP, which suppresses the electron injection from the conduction band of the barrier layer of the InGaAsP into the current blocking layer made of InP. On the other hand, when the barrier layer is made of AlGaInAs, as shown in FIG. 2B, the bottom level of the conduction band in the AlGaInAs barrier layer is higher than that of the InP in the p-type current blocking layer. Accordingly, the electron injection from the conduction band of the barrier layer of the AlGaInAs into the p-type current blocking layer made of InP may be easily occurred. In the light-emitting device with the quantum well structure for the active region, the generation of photons, the light emission, occurs in the well layer by recombine the electron in the conduction band with the hole in the valence band. The electrons are transported through the conduction band of the barrier layer. When the barrier layer is made of AlGaInAs, as described above, a portion of the electrons transported in the barrier layer may be escaped therefrom to the p-type current blocking layer.

The thyristor with the p-n-p-n junctions has a characteristic that, when minority carriers are injected in the inner n-type or p-type layers, these minority carriers may turn on the thyristor, which drastically increase the current flowing in the device. The electron behaves as the minority carrier for the p-type current blocking layer. Accordingly, when the electron transported in the barrier layer is injected to the p-type current blocking layer, the leak current flowing in the current blocking layer strongly increases. Increasing the supply current to the active region with the AlGaInAs barrier layer to get the large optical power, the electron injection from the AlGaInAs barrier layer to the p-type InP current blocking layer is abruptly accelerated, which increases the leak current in the current blocking layer. Such increase of the leak current is due to the mechanism that the material of the barrier layer has the higher level in the bottom of the conduction band than that of the InP. When the barrier layer is made of InGaAsP, such increase of the leak current does not occur. In the present embodiment, the band gap energy of the barrier layer is smaller than or equal to the energy corresponding to the band gap frequency of 1.0 μm. To make small the band gap energy of the barrier layer lowers the bottom level of the conduction band of the AlGaInAs, which reduces the electron injection from the barrier layer into the p-type InP current blocking layer. Thus, the turning on the parasitic thyristor may be effectively suppressed to lower the leak current when the large current is supplied to the light-emitting device.

### Second Embodiment

The second embodiment of the present invention has a first III-V semiconductor material for the barrier layer with a tensile stress. The light-emitting device 11 according to the second embodiment, because the bottom level of the conduction band in the barrier layer may be lowered, the leak current flowing in the current blocking layer may be further reduced. Moreover, the well layer 29 may have a second III-V semiconductor material with a compressive stress to compensate the tensile stress in the barrier layer.

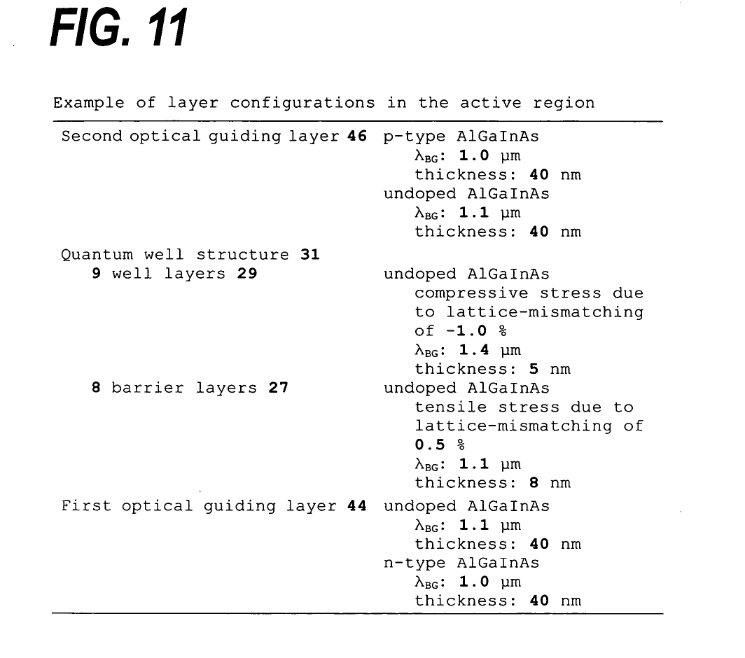

An example of layer configurations in the active region 17 according to the second embodiment will be shown in FIG. 11. This example is a type of the compressive stress in the well layers, while, the tensile stress in the barrier layers.

The lattice mismatching Δa/a in the well layers is greater than or equal to −1.5% and is smaller than or equal to −0.7%, where a is the lattice constant of the InP, while Δa is a difference in the lattice constant between the InP and the lattice mismatched material. The lattice mismatching Δa/a in the barrier layer is greater than or equal to 0.5% and smaller than or equal to 1.0%.

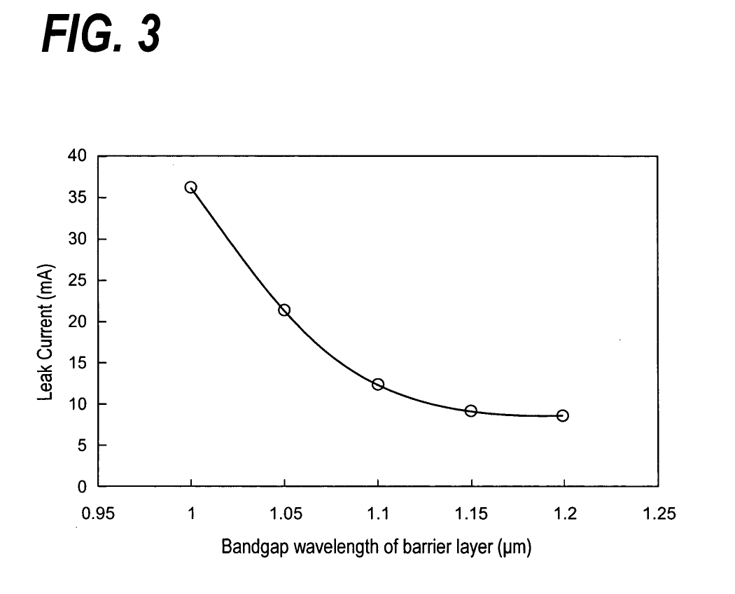

A simulation for the leak current flowing in the current blocking layer was carried out based on a simplified model of the second embodiment shown above. In this calculation, the leak current was investigated as varying the band gap energy of the barrier layer. FIG. 3 indicates the leak current in the vertical axis under a condition that a current of 100 mA is supplied to the device, while, the horizontal axis corresponds to the band gap energy of the barrier layer. According to FIG. 3, the leak current decreases when the band gap wavelength of the barrier layer becomes greater than 1.0 μm. When the band gap wavelength is greater than or equal to 1.15 μm, the gradualness of the decrease in the leak current becomes smaller. Thus, the barrier layer with the band gap wavelength greater than or equal to 1.0 μm may reduce the leak current. When the band gap wavelength is 1.05 μm, the leak current may be reduced to about 60% of the case where the band gap wavelength is 1.0 μm. When the band gap wavelength is about 1.1 μm, the leak current may be reduce to about 35% of the case where the band gap wavelength is 1.0 μm.

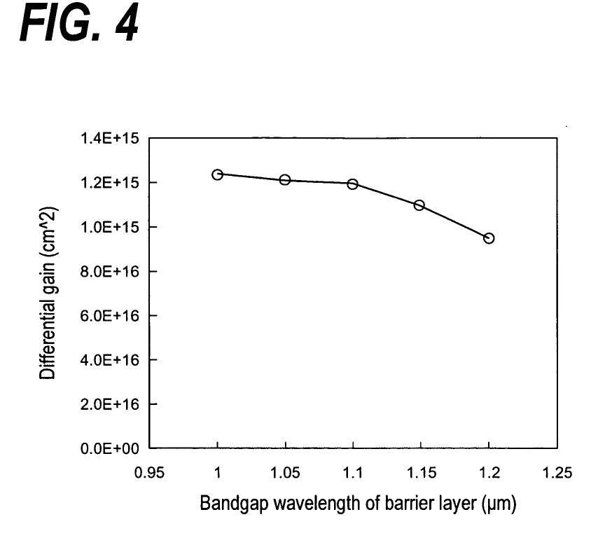

FIG. 4 is a calculative result of the differential gain against the band gap wavelength of the AlGaInAs barrier layer in the horizontal axis, while, the differential gain of the light-emitting device in the vertical axis by the cm² unit. In the region where the band gap wavelength of the barrier layer is smaller than 1.1 μm, the differential gain shows a nearly flat characteristic of about 1.2×10⁻¹⁵ cm². Exceeding 1.1 μm, the differential gain gradually decreases from the flattened value 1.2×10⁻¹⁵ cm², and becomes about 1.1×10⁻¹⁵ cm². Finally, the differential gain decreases to 1.0×10⁻¹⁵ cm² at the band gap wavelength 1.2 μm.

Thus, the band gap wavelength is preferably greater than or equal to 1.05 μm for the laser diode with the quantum well structure including the AlGaInAs barrier layer and with the current blocking layer including p-type and n-type InP from the view point of the leak current in the current blocking layer. On the other hand, the band gap wavelength is preferably smaller than or equal to 1.15 μm from the viewpoint of the differential gain. Thus, the band gap wavelength is preferably about 1.1 μm to show the consistent characteristic between the leak current and the differential gain. Depending on the application of the semiconductor laser where the differential gain is emphasized, the band gap wavelength of the barrier layer may be about 1.05 μm.

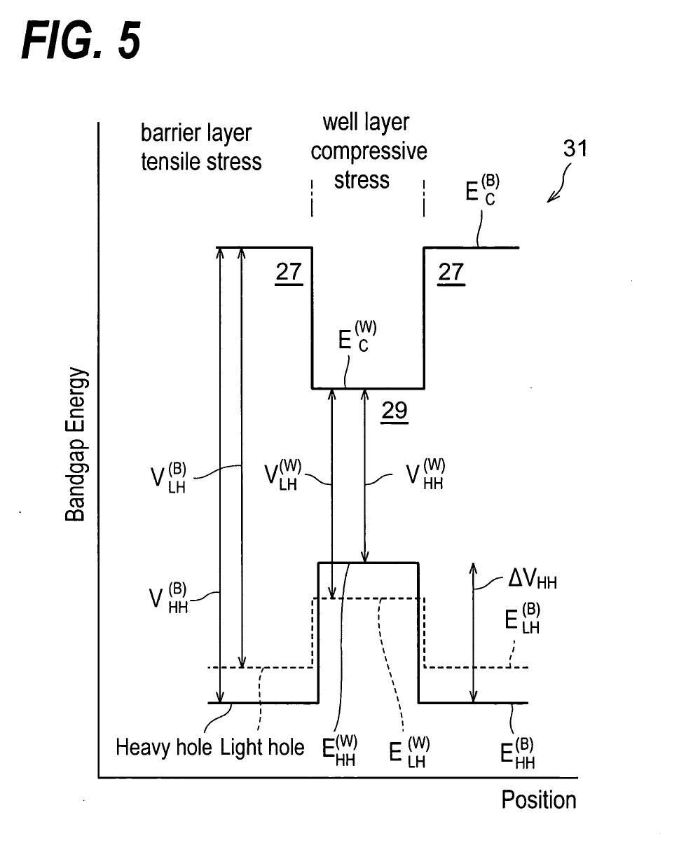

Next, merits to have the tensile or compressive stress in the barrier or well layers, respectively, will be explained below as referring to FIG. 5 that is a band diagram of the quantum well structure 31 comprising the barrier 27 with the tensile stress and the well layer 29 with the compressive stress. The tensile stress induces the valence band to sprit it into a heavy hole band and a light hole band, and to raise the level of the light hole band, while, to lower the heavy hole band. On the other hand, the compressive stress applied in the well layer also sprits the valence band into the heavy hole band and the light hole band. However, in the compressive stress, the heavy hole band is raised, while, the light hole band is lowered.

Accordingly, in the well layer 29, a difference V_{HH}^{(W)} between the top level E_{HH}^{(W)} of the valence band for the heavy hole (HH) and the bottom level E_{C}^{(W)} of the conduction band is smaller than a difference V_{LH}^{(W)} between the top level E_{LH}^{(W)} of the valence band for the light hole (LH) and the bottom level E_{C}^{(W)} of the conduction band. While, in the barrier layer 27, the energy difference V_{HH}^{(B)} between the top level E_{HH}^{(B)} for the heavy hole band and the bottom level E_{C}^{(B)} for the electron is greater than the energy difference V_{LH}^{(B)} between the top level E_{LH}^{(B)} for the light hole band and the bottom level E_{C}^{(B)} for the electron. The band gap wavelength of the barrier layer 27 corresponds to the difference V_{LH}^{(B)} between the energy level E_{LH}^{(B)} for the light hole band and the that E_{C}^{(B)} for the conduction band. The emission of the light in the quantum well structure 31 occurs between the top level E_{HH}^{(W)} of the heavy hole band and the bottom level E_{C}^{(W)} of the conduction band. Moreover, the quantum effect for the heavy hole is caused by the band discontinuity ΔV_{HH} between the heavy hole band E_{HH}^{(W)} in the well layer 29 and that E_{HH}^{(B)} in the barrier layer 27. Accordingly, the effective band gap energy that causes the quantum effect in the well layer becomes the top level V_{HH}^{(B)} between the energy level E_{C}^{(B)} and the energy level of the heavy hole band E_{HH}^{(B)}.

To reduce the leak current is necessary to lower the level of the conduction band. The description above concentrates on a state where the level of the conduction band may be lowered by increasing the band gap wavelength. However, another configuration where the tensile and compressive stresses are induced in the barrier and well layers, respectively, may also lower the level of the conduction band. In the light-emitting device with the AlGaInAs material, when increasing the band gap wavelength, namely, decreasing the band gap energy, about 72% of the increase lowers the level of the conduction band, while rest 28% contributes to raise the level of the valence band.

To raise the level of the valence band in the barrier layer decreases the energy difference from the valence band of the well layer, which also reduces the quantum effect to, for instance, follow the decrease of the differential gain. When the compressive stress and the tensile stress are induced in the well layer and the barrier layer, respectively, the band gap wavelength may be widened by the stress, that is, the band gap energy becomes smaller. About 92% of the increase in the band gap wavelength contributes to lower the conduction band, while rest 8% thereof contributes to lower the valence band. This valence band corresponds to the heavy hole band. The band gap wavelength corresponds to the effective band gap energy, that is, the difference V_{HH}^{(B)} in FIG. 5.

Under the configuration that the compressive and tensile stresses are induced in the well and barrier layers, respectively, even when the band gap wavelength corresponding to the effective band gap energy is equal to the band gap wavelength of the barrier layer without the tensile stress, the level of the conduction band is lowered to be effective to reduce the leak current.

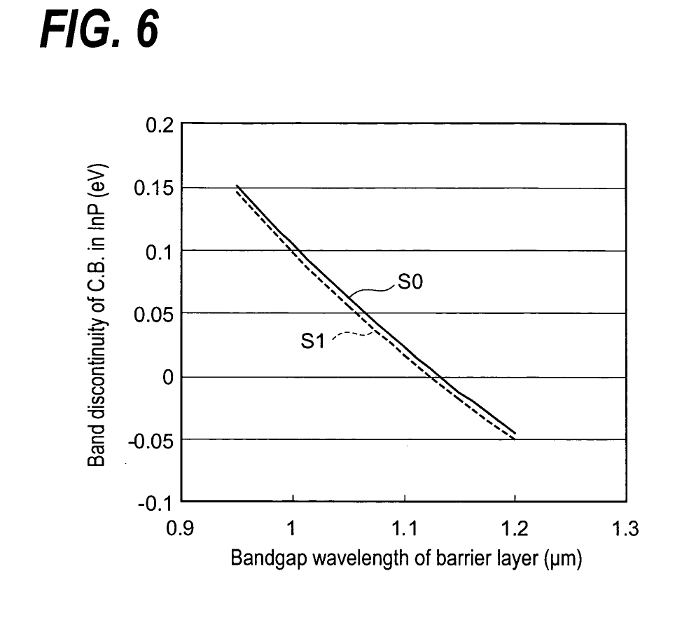

FIG. 6 compares the band discontinuity to the InP in the conduction band of the AlGaInAs barrier layer lattice-matched with the InP, namely, no tensile stress is induced, and the AlGaInAs barrier layer with the tensile stress corresponding to the 0.5% lattice-mismatching. The line S0 shows the discontinuity of the AlGaInAs lattice-matched to the InP, while, a line S1 corresponds to a case where the AlGaInAs barrier layer with the tensile stress due to the 0.5% lattice-mismatching to the InP and the AlGaInAs well layer with the compressive stress. The horizontal axis shows the band gap wavelength corresponding to the effective band gap energy V_{HH}^{(B)} that shows the effective quantum effect. When the barrier layer induces the tensile stress, the band discontinuity to the InP reduces, which advantages to decrease the leak current.

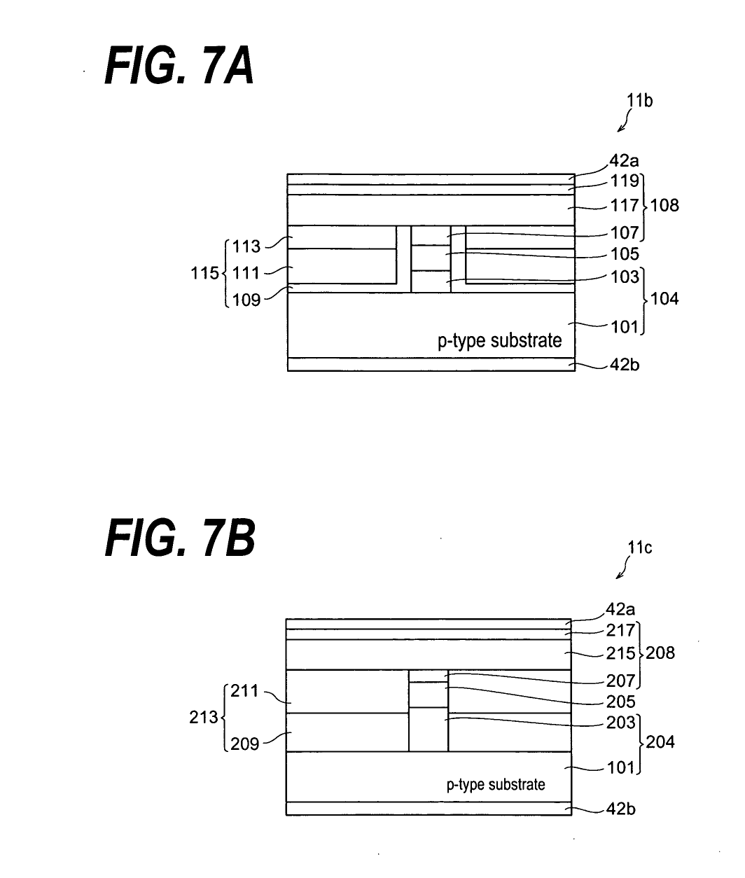

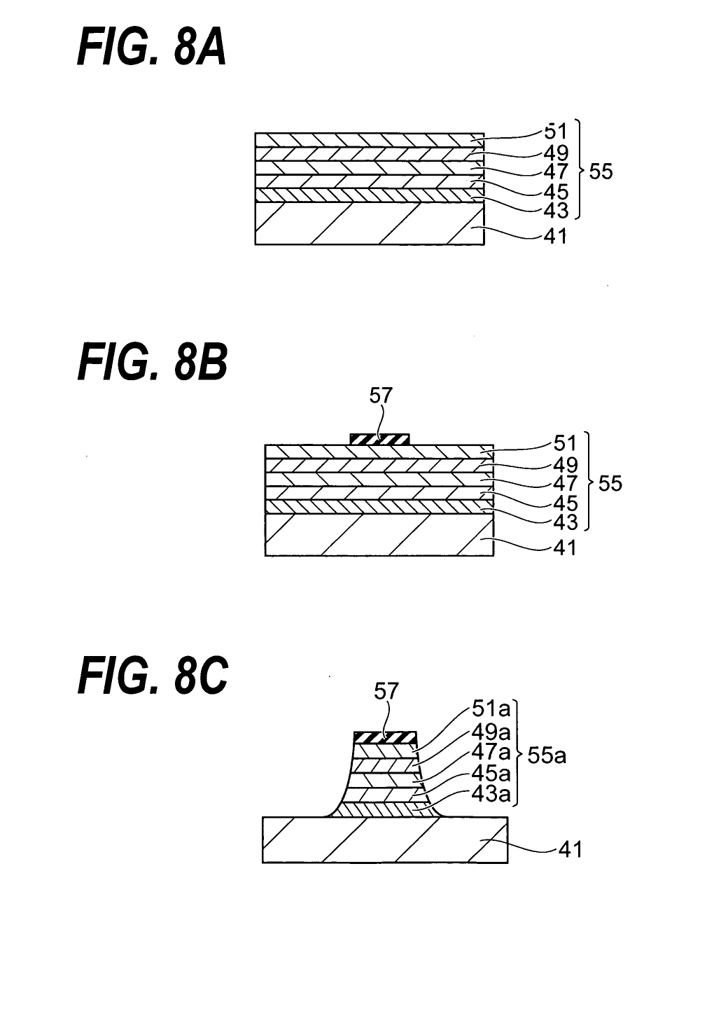

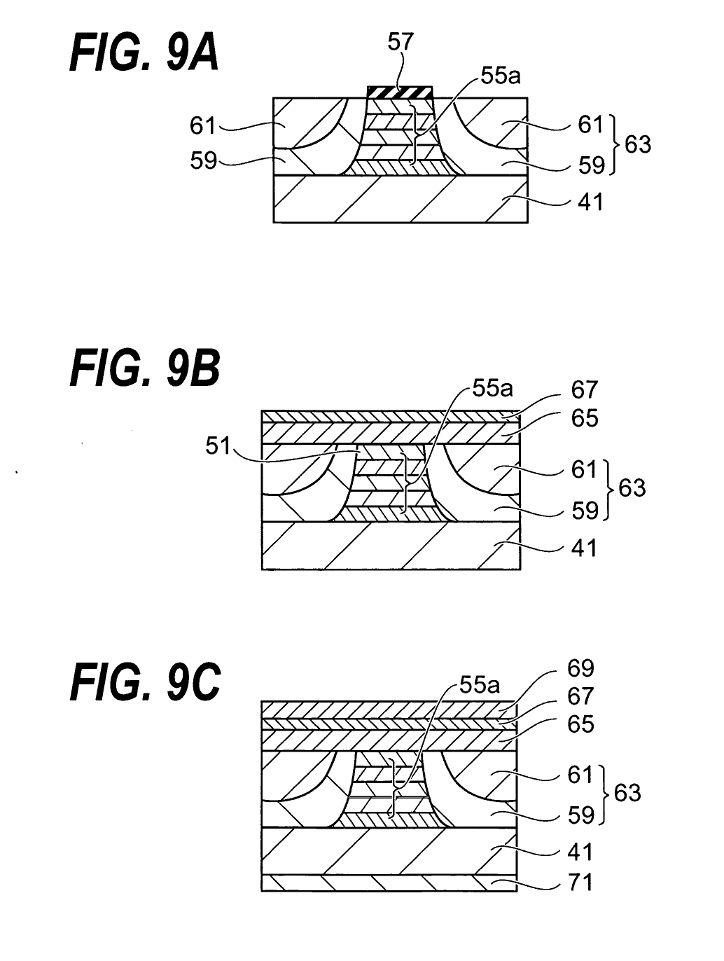

FIG. 7A shows a modification of the present embodiment. The light-emitting device 11b has a buried region 115, an active region 105 including a quantum well structure, a p-type region 104, and an n-type region 108. The buried region 115 includes a first p-type buried layer 109, an n-type buried layer 111, and a second p-type buried layer 113, and covers sides of the active region 105. The p-type region 104 may include a p-type InP substrate 101 and a p-type InP cladding layer 103. The n-type region 108 may include a first n-type cladding layer 107, a second n-type cladding layer 117 made of InP, and a contact layer 119 made of InGaAs.

The barrier layer induces the tensile stress, while, the well layer induces the compressive stress. Similar to the first embodiment, the quantum well structure includes a first barrier layer 27 formed by a first III-V semiconductor material containing aluminum, gallium, indium, and arsenic, and a well layer 29 formed by a second III-V semiconductor material. The active region 105 and the buried region 115 are formed on the p-type regions, 101 and 103. On the sides of the active region 105 are provided with the p-type buried region 109. The band gap energy of the first material for the barrier layer 27 is smaller than or equal to a value corresponding to the band gap wavelength of 1.0 μm. Accordingly, the injection of the minority carrier, the electrons in this case, from the active region 105 into the p-type buried layer 109 may be suppressed. Accordingly, the leak current caused by turning on the parasitic thyristor formed by layers, 101, 109, 111, 113, and 117, may be prevented from increasing.

FIG. 7B shows still another modification of the present embodiment. The light-emitting device 11c has an active region 205 with the quantum well structure, a buried region 213 with an n-type buried layer and a p-type buried layer and formed in the sides of the active region 205, a p-type region 204, and an n-type region 208. The p-type region 204 may include a p-type InP substrate 101 and a p-type InP cladding layer 203.

The n-type region 208 may include a first n-type cladding layer 207, a second cladding layer 215 of the n-type InP, and a contact layer 217. Similar to the first embodiment, the quantum well structure comprises a barrier layer 27 formed by a first III-V semiconductor material containing aluminum, gallium, indium, and arsenic, and a well layer 29 formed by a second III-V semiconductor material. The active region 205 and the buried region 213 are formed on the p-type region 204. On the sides of the p-type region 205 are covered by the p-type buried layer 211. The band gap energy of the barrier layer 27 is smaller than or equal to a value corresponding to the band gap wavelength of 1.0 μm. Accordingly, the leak current caused by turning on the parasitic thyristor formed by layers, 101, 209, 211, and 215, may be prevented from increasing.

According to the embodiments and modifications thereof, light-emitting devices, 11, 11b, and 11c, are provided, which comprises an active region with a quantum well structure containing the AlGaInAs and an emitting wavelength in the 1.3 μm band, and has a characteristic with the reduced leak current.

### Third Embodiment

Next, a method for manufacturing a light-emitting device according to the present invention will be described as referring to FIGS. from 8A to 9C. In FIG. 8A, an n-type InP substrate 41 is prepared. A series of films is grown on this InP substrate 41, that is, a cladding film 43 made of an n-type InP, a lower separated-confinement-hetero-structure (SCH) film 45 made of an AlGaInAs, a multi-quantum well (MQW) region 47, an upper SCH film 49 made of an AlGaInAs, and a cladding film 51 made of a p-type InP, are grown on the InP substrate in this order. The growth of these films may be carried out in the apparatus of the Organo-Metallic Vapor-phase Epitaxy (OMVPE) technique. The MQW region 47 includes a barrier film made of the AlGaInAs with a band gap wavelength thereof greater than or equal to 1.05 μm and smaller than or equal to 1.15 μm, and a well film with a band gap wavelength longer than that of the barrier film, for example, 1.4 μm.

As shown in FIG. 8B, a mask 57 for forming the mesa is prepared on the stack 55. This mask, made of dielectric film such as silicon nitride and silicon dioxide, has a width from 1 to 4 μm.

As shown in FIG. 8C, a stripe 55a is formed by etching the stack 55 using this mask 57. This may be carried out by, what is called, the dry-etching, the wet-etching, or by using both etchings, to expose the substrate 41. Thus, the stripe 55a includes the n-type cladding film 43a, the lower SCH film 45a, the MQW region 47a, the upper SCH film 49a, and the p-type cladding film 51a.

Next, the buried region 63 is formed. In the embodiment shown in FIG. 9A, the sides of the stripe 55a and the top of the substrate 41 are covered with a p-type current blocking film 59. This current blocking film 59 covers the sides of the lower SCH film 45a, the MQW region 47a, the upper SCH film 49a, and at least a portion of the p-type cladding film 51a. Next, an n-type current blocking film 61 is grown on the p-type current blocking film. These growths of the p-type and n-type current blocking films, 59 and 61, are carried out without removing the dielectric mask 57. These two films, 59 and 61, operate as a current blocking region because they bury the stripe 55a. After the growth of these two films, 59 and 61, the dielectric mask 57 is removed.

Next, on the buried region 63 is formed by a cladding film 65 made of a p-type InP, and a contact film 67 made of a p-type InGaAs. The total thickness of the p-type cladding film in the stripe 55a and the p-type cladding film 65 becomes about 2 μm.

On the p-type contact film 67 is formed by a p-type electrode 69 of a stacked metals of titanium, platinum, and gold, while in the back surface of the substrate 41 is formed by an n-type electrode 71 of alloyed metals of gold-germanium, nickel, and gold, as shown in FIG. 9C. The substrate 41 may be thinned to about 100 μm before the formation of electrode 71.

Thus, according to the method of the present embodiment, a light-emitting device may be formed, where the device includes an active layer containing the AlGaInAs for the barrier layer, a p-type InP buried layer, and an n-type InP buried layer, and reduces the leak current flowing in the buried layer. Materials for the well layer that fits to the AlGaInAs barrier layer are not restricted to the AlGaInAs, for example, the well layer of the InGaAsP may be applicable to the present invention.

While the present invention has been described in particular embodiments, it should be appreciated for those skilled in the field that the present invention should not be construed as limited by such embodiments. For example, the light-emitting device may be a laser diode, a light-amplifying device, and a light emitting diode. Accordingly, it will be understood that the following claims are not to be limited to the embodiments disclosed herein, can include practices otherwise than specifically described, and are to be interpreted as broadly as allowed under the law.

What is claimed is:

1. A semiconductor light-emitting device, comprising:
a semiconductor substrate made of a III-V compound semiconductor material with a first conduction type;
an active region arranged on the semiconductor substrate and having a quantum well structure including a barrier layer and a quantum well layer, the barrier layer being made of a first III-V compound semiconductor material with a band gap wavelength greater than or equal to 1 μm and containing aluminum, gallium, indium and arsenic, the quantum well layer being made of a second III-V compound semiconductor material; and
a buried semiconductor region arranged on the semiconductor substrate and provided on sides of the active region, the buried semiconductor region including a first buried semiconductor layer with a second conduction type different from the first conduction type and a second buried semiconductor layer with the first conduction type, the second buried semiconductor layer being arranged on the first buried semiconductor layer, the first buried semiconductor layer with the second conduction type being in contact with the active region,
wherein the barrier layer is induced by a tensile stress.

2. The semiconductor light-emitting device according to claim 1,
wherein the quantum well layer is induced by a compressive stress.

3. The semiconductor light-emitting device according to claim 1,
wherein the first III-V semiconductor material has a band gap wavelength longer than or equal to 1.05 μm.

4. The semiconductor light-emitting device according to claim 1,
wherein the first III-V semiconductor material has a band gap wavelength smaller than or equal to 1.15 μm.

5. The semiconductor light-emitting device according to claim 1,
wherein the second III-V compound semiconductor material contains aluminum, gallium, indium and arsenic.

6. The semiconductor light-emitting device according to claim 1,
wherein the first and second buried semiconductor layer are made of InP.

7. The semiconductor light-emitting device according to claim 1,
wherein the semiconductor substrate is made of InP.

8. A light-emitting device, comprising:
an n-type InP substrate;
an n-type cladding layer stacked on the n-type InP substrate;
an active region stacked on the n-type cladding layer, the active region having a quantum well structure including a barrier layer made of AlGaInAs with a tensile stress and a quantum well layer mad of AlGaInAs;
a buried semiconductor region provided on sides of the active region and the n-type InP substrate, the buried semiconductor region including a p-type buried layer made of InP and an n-type buried layer made of InP stacked on the p-type buried layer, the p-type buried layer being in contact with the barrier layer in the active region; and
a p-type cladding layer stacked on the active region and the buried semiconductor region,
wherein the AlGaInAs of the barrier layer has a band gap wavelength greater than or equal to 1 μm.

9. A light-emitting device, comprising:
a p-type semiconductor substrate;
an active region with a quantum well structure including a barrier layer made of AlGaInAs with a tensile stress and a quantum well layer made of AlGaInAs with a composition different from a composition of the AlGaInAs of the barrier layer, the active region being arranged on the p-type substrate; and
a buried region arranged on both sides of the active region, the buried region including a first p-type layer made of InP, an n-type layer, and a second p-type layer, the first p-type layer covering sides of the active region, the n-type layer being stacked on the first p-type layer, the second p-type layer being stacked on the n-type layer,
wherein the AlGaInAs of the barrier layer has a band gap wavelength greater than or equal to 1 μm.

10. A light-emitting device, comprising:
a p-type semiconductor substrate;
an active region with a quantum well structure including a barrier layer made of AlGaInAs with a tensile stress and a quantum well layer made of AlGaInAs with a composition different from a composition of the AlGaInAs of the barrier layer, the active region being arranged on the p-type substrate; and
a buried region arranged on both sides of the active region, the buried region including a p-type layer made of InP and an n-type layer, the p-type layer being in contact with the active region,
wherein the AlGaInAs of the first barrier layer has a band gap wavelength greater than or equal to 1 μm.
